(19) United States
(12) Patent Application Publication
(10) Pub. No.: US 2025/0329549 A1
(43) Pub. Date: Oct. 23, 2025

(54) SEMICONDUCTOR DEVICE MANUFACTURING METHOD

(71) Applicant: Resonac Corporation, Minato-ku, Tokyo (JP)

(72) Inventor: Katsuhiko SUZUKI, Minato-ku, Tokyo (JP)

(21) Appl. No.: 18/857,189

(22) PCT Filed: Nov. 4, 2022
(86) PCT No.: PCT/JP2022/041199

§ 371 Date: Jul. 10, 2025

(51) Int. Cl. H01L 21/56; H01L 23/00

(52) U.S. Cl. CPC H01L 21/561; H01L 21/568; H01L 24/19; H01L 24/24; H01L 24/95; H01L 24/96; H01L 2224/19; H01L 2224/24137; H01L 2224/95001; H01L 2224/96

(57) ABSTRACT

A method for manufacturing a semiconductor device includes preparing a laminate in which each of a plurality of semiconductor chips is fixed on a carrier by an adhesive layer, wherein the plurality of semiconductor chips are fixed on a first carrier surface of the carrier such that each connection terminal of the plurality of semiconductor chips faces away from the carrier, forming a re-distribution layer that connects to each connection terminal of the plurality of semiconductor chips, and grinding the carrier in the laminate from a second carrier surface opposite to the first carrier surface toward the first carrier surface. In the grinding, the carrier and the adhesive layer are scraped off to expose second chip surfaces of the plurality of semiconductor chips, wherein the second chip surfaces are located on opposite side of the first chip surfaces on which the re-distribution layer is provided.

### TECHNICAL FIELD

The present disclosure relates to a method for manufacturing a semiconductor device.

### BACKGROUND ART

Patent Literature 1 discloses an example of a fan-out semiconductor device. In this semiconductor device, a re-distribution layer is provided between a semiconductor chip and external connection terminals, and the semiconductor chip is connected to the external connection terminals with each terminal interval being widened by the re- distribution layer.

### CITATION LIST

### Patent Literature

Patent Literature 1: Japanese Unexamined Patent Publication No. 2019-029557

### SUMMARY OF INVENTION

### Technical Problem

In a conventional method for manufacturing a semiconductor device, for example, as illustrated in (a) of FIG. 5, a plurality of semiconductor chips 110 are temporarily fixed on a glass carrier 120 with a temporary fixing material 112 and encapsulated them with an encapsulant 130. Then, the encapsulant 130 is polished until a connection terminal of the semiconductor chips 110 are exposed, and a re-distribution layer 140 (see (b) of FIG. 5) is formed thereon. However, the semiconductor chip 110 is temporarily fixed to the carrier 120 by the temporary fixing material 112 in this method for manufacturing a semiconductor device, and thus a so-called die shift S1 in which the semiconductor chip 110 moves from an initial installation position due to the pressure may occur when the encapsulant 130 is molded by a molding machine. In a case where the die shift occurs, a separate alignment operation is required for a subsequent step (for example, an exposure step).

In addition, an outer peripheral portion S2 in which the temporary fixing material 112 is sandwiched between the glass carrier 120 and the encapsulant 130 is exposed, and thus may be damaged due to the influence of a chemical solution to be used. As a result, there is a possibility that the glass carrier 120 and the encapsulant 130 are peeled off in the middle of the process. Furthermore, as illustrated in (b) of FIG. 5, when the temporary fixing material 112 is peeled off from the encapsulant 130, a crack may be generated between the semiconductor chip 110 and the encapsulant 130 by a force during peeling. A resin residue of the temporary fixing material 112 may remain on a surface of the encapsulant 130 or the semiconductor chip 110 (S3), microcracks S4 may be generated in the glass carrier 120 during the process, or metal S5 used in the process may be mixed into the microcracks S4.

An object of the present disclosure is to provide a method for manufacturing a semiconductor device capable of easily improving cleanliness of a chip surface while preventing displacement of a semiconductor chip.

### Solution to Problem

As one aspect, the present disclosure relates to a method for manufacturing a semiconductor device. This manufacturing method includes preparing a laminate in which each of a plurality of semiconductor chips is fixed on a carrier by an adhesive layer, wherein the plurality of semiconductor chips are fixed on a first carrier surface of the carrier such that each connection terminal of the plurality of semiconductor chips faces away from the carrier, forming a re-distribution layer that connects to each connection terminal of the plurality of semiconductor chips, and grinding the carrier in the laminate from a second carrier surface opposite to the first carrier surface toward the first carrier surface. In the grinding, the carrier and the adhesive layer are scraped off to expose second chip surfaces of the plurality of semiconductor chips, wherein the second chip surfaces are located on opposite side of first chip surfaces on which the re-distribution layer is provided.

In this method for manufacturing a semiconductor device, the plurality of semiconductor chips are fixed on the carrier by the adhesive layer. As described above, the semiconductor chips are fixed on the carrier by the adhesive layer that performs fully fixing instead of temporary fixing. In this case, displacement of the semiconductor chips is reliably prevented. In addition, in this method for manufacturing a semiconductor device, in the grinding, the carrier is scraped off to expose the second chip surfaces of the plurality of semiconductor chips, wherein the second chip surfaces are located on opposite side of the first chip surfaces on which the re-distribution layer is provided. In this case, since the carrier is scraped off, it is possible to improve cleanliness of a chip surface without leaving a resin residue or the like.

In the above-described method for manufacturing a semiconductor device, the adhesive layer may be a layer obtained by curing a thermosetting adhesive and provided to correspond to each of the plurality of semiconductor chips. In this case, the adhesive layer can be easily ground in the grinding of the carrier.

In the above-described method for manufacturing a semiconductor device, a thickness of the adhesive layer is preferably 50 μm or less. In this case, the adhesive layer can be easily ground in the grinding of the carrier. Note that the thickness of the adhesive layer is more preferably 20 μm or less. In this case, the adhesive layer can be ground more easily.

In the method for manufacturing a semiconductor device, the adhesive layer preferably includes a curable resin component and an inorganic filler, and the content of the inorganic filler is preferably 50% by mass to 95% by mass based on a total amount of an adhesive before the adhesive layer is cured. In this case, the adhesive layer can be easily ground in the grinding of the carrier. Note that the content of the inorganic filler is more preferably 80% by mass to 95% by mass based on the total amount of the adhesive before the adhesive layer is cured. In this case, the adhesive layer can be ground more easily in the grinding of the carrier.

In the above-described method for manufacturing a semiconductor device, the preparing the laminate may include fixing each of the plurality of semiconductor chips to the carrier with the adhesive layer, and forming an encapsulant layer by encapsulating the plurality of semiconductor chips on the carrier with an encapsulant to cover the plurality of semiconductor chips. In this aspect, the encapsulant may include a curable resin component and an inorganic filler, and the content of the inorganic filler in the encapsulant may be 50% by mass or more, and is preferably 80% by mass or more, based on a total amount of the encapsulant. In this case, the encapsulant layer can be reliably ground.

In the method for manufacturing a semiconductor device, the preparing the laminate may further include grinding the encapsulant layer covering the plurality of semiconductor chips until the first chip surfaces of the plurality of semiconductor chips are exposed, after the encapsulating.

In the above-described method for manufacturing a semiconductor device, the grinding of the carrier preferably includes rough-grinding the second carrier surface of the carrier with a first grindstone, and finish-grinding the roughly ground carrier with a second grindstone having a higher grain size than the first grindstone. In this case, grinding speed of the carrier can be accelerated by the rough-grinding, and the finish of the surface ground by the finish-grinding can be improved. In this aspect, the first grindstone may be a grindstone having a grain size of #200 to #1000, and the second grindstone may be a grindstone having a grain size of #2000 to #6000. As a result, it is possible to more reliably improve the grinding speed and finish accuracy of the ground surface. In this aspect, the carrier and at least a part of the adhesive layer may be scraped off by the first grindstone in the rough-grinding, and the encapsulant layer and the second chip surfaces of the semiconductor chips may be polished by the second grindstone in the finish-grinding. As a result, it is possible to more reliably improve the grinding speed and the finish accuracy of the ground surface.

In the above-described method for manufacturing a semiconductor device, the carrier may be a silicon carrier, and the grinding may further include recovering ground silicon sludge (silicon waste) for reuse. In this case, the used silicon can be reused, and the manufacturing method can be made environmentally friendly. For example, impurities can be removed from the ground silicon sludge for reuse as regenerated silicon according to this manufacturing method.

### Advantageous Effects of Invention

According to the present disclosure, it is possible to provide the method for manufacturing a semiconductor device capable of easily improving the cleanliness of the chip surface while preventing the displacement of the semiconductor chip.

### BRIEF DESCRIPTION OF DRAWINGS

FIG. 1 is a cross-sectional view illustrating an example of a semiconductor device.

FIG. 2 (a) to (c) of FIG. 2 are views sequentially illustrating a method for manufacturing a semiconductor device.

FIG. 3 (a) to (b) of FIG. 3 are views sequentially illustrating the method for manufacturing a semiconductor device, and illustrate steps performed following steps in FIG. 2.

FIG. 4 (a) to (c) of FIG. 4 are views sequentially illustrating the method for manufacturing a semiconductor device, and illustrate steps performed following the steps in FIG. 3.

FIG. 5 (a) to (b) of FIG. 5 are views illustrating a method for manufacturing a semiconductor device according to a comparative example.

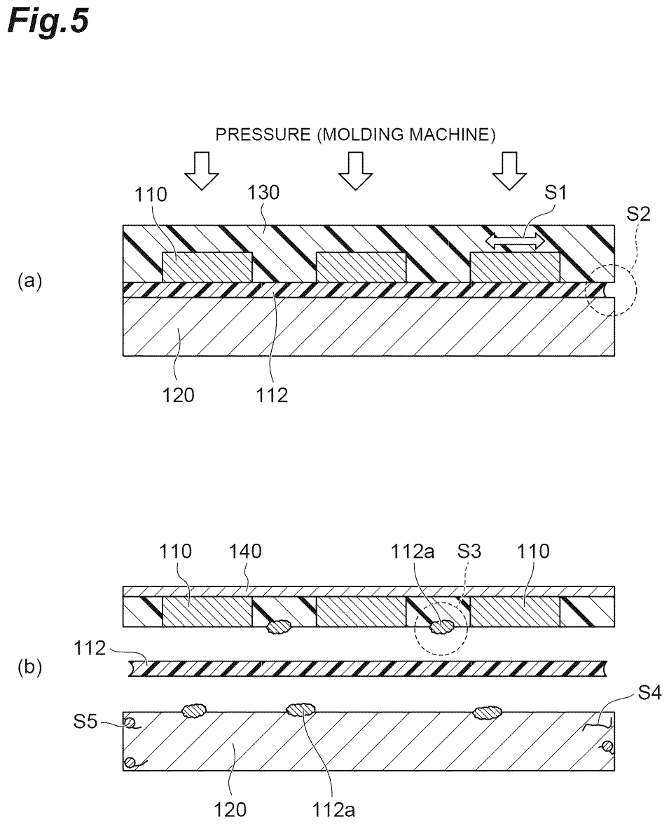

### DESCRIPTION OF EMBODIMENTS

Hereinafter, the present embodiment will be described in detail with reference to the drawings. In the following description, the same or corresponding portions will be denoted by the same reference signs, and redundant description will be omitted. A positional relationship such as the left, right, top, or bottom is based on a positional relationship illustrated in the drawings unless otherwise specified. A dimensional ratio in the drawings is not limited to the illustrated ratio.

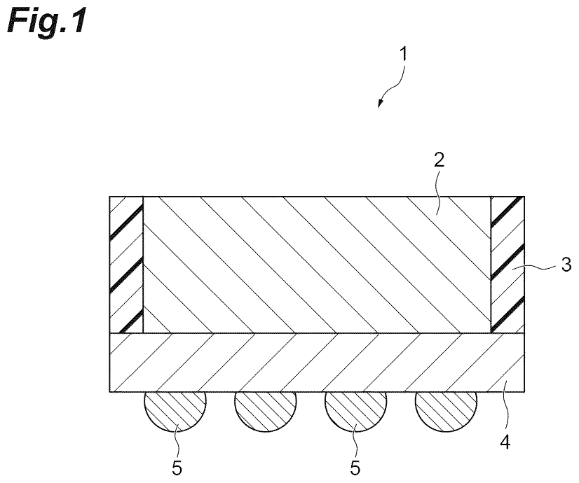

When terms such as “left”, “right”, “front”, “rear”, “top”, “bottom”, “upper”, “lower”, “first”, and “second” are used in the present specification and claims, these are intended to be illustrative and do not necessarily mean that these are in such relative positions at all times. The term “layer” includes not only a structure having a shape formed on the entire surface but also a structure having a partially formed shape when observed as a plan view. The term “step” includes not only an independent step but also a step whose intended purpose is achieved even if the step cannot be clearly distinguished from other steps. A numerical range represented by using “to” indicates a range including numerical values described before and after “to” as a minimum value and a maximum value, respectively. In a numerical range described in stages in the present specification, an upper limit value or a lower limit value of the numerical range at one stage may be replaced with an upper limit value or a lower limit value of the numerical range at another stage. FIG. 1 is a cross-sectional view illustrating an example of a semiconductor device. As illustrated in FIG. 1, a semiconductor device 1 includes a semiconductor chip 2, a protective portion 3, a re-distribution layer 4, and bumps 5. The semiconductor chip 2 is, for example, a semiconductor chip such as a processor or a memory. The protective portion 3 is a portion made of an encapsulating resin or the like and protects the semiconductor chip 2. The re-distribution layer 4 (RDL) is a wiring layer having an insulating portion and a wiring (for example, copper wiring) formed in the insulating portion. The re-distribution layer 4 connects connection terminals of the semiconductor chip 2 and the bumps 5. The bumps 5 are made of, for example, a metal material such as solder.

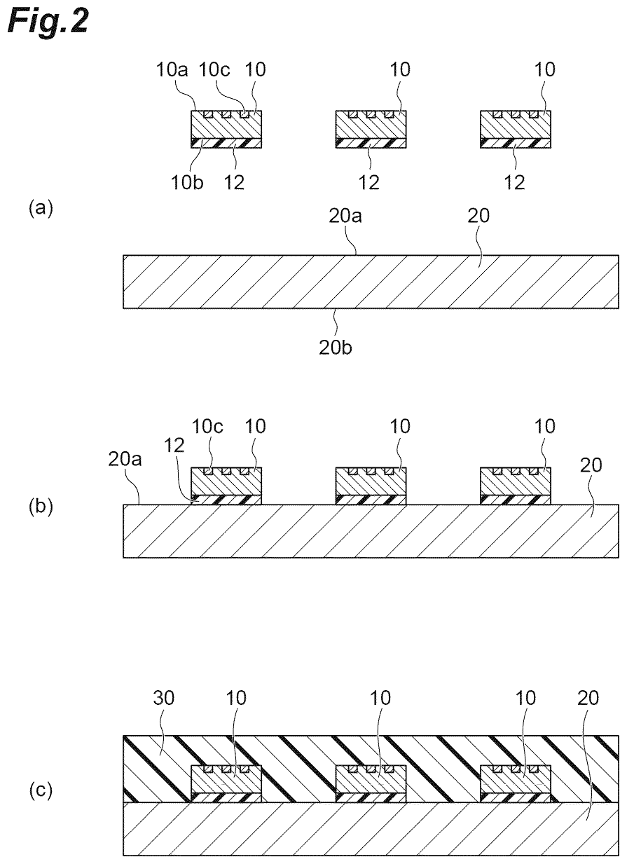

Next, a method for manufacturing the semiconductor device 1 will be described with reference to FIG. 2 to FIG. 4 are views sequentially illustrating the method for manufacturing the semiconductor device 1. The semiconductor device 1 is manufactured, for example, through the following steps (a) to (d).
(a) A step of preparing a laminate T1 in which each of a plurality of semiconductor chips 10 is fixed on a carrier 20 by an adhesive layer 12. In this step (a), the plurality of semiconductor chips 10 are fixed on a first carrier surface 20a of the carrier 20 such that each connection terminal 10c of the plurality of semiconductor chips 10 faces away from the carrier 20.
(b) A step of forming a re-distribution layer 40 that connects to each connection terminal 10c of the plurality of semiconductor chips 10.
(c) A step of grinding the carrier 20 in a laminate T2 from a second carrier surface 20b opposite to the first carrier surface 20a toward the first carrier surface 20a. In this step (c), the carrier 20 and the adhesive layer 12 are scraped off to expose the second chip surfaces 10b of the plurality of semiconductor chips 10, wherein the second chip surfaces 10b are located on opposite side of the first chip surfaces 10a on which the re-distribution layer 40 is provided.
(d) A step of dicing a laminate T3 from which the carrier 20 has been scraped off into individual pieces to obtain semiconductor devices each including the semiconductor chip 10. In this step (d), a predetermined number of bumps (corresponding to the bumps 5 in FIG. 1) are formed in the re-distribution layer 40 before the dicing.

In the step (a), first, the plurality of semiconductor chips 10 are prepared as illustrated in (a) of FIG. 2. The adhesive layer 12 is attached to each of the semiconductor chips 10. The semiconductor chip 10 corresponds to the semiconductor chip 2 in the semiconductor device 1 illustrated in FIG. 1. The semiconductor chip 10 has the first chip surface 10a on which the connection terminals 10c are provided and the second chip surface 10b located on opposite side of the first chip surface 10a. The adhesive layer 12 is bonded to the second chip surface 10b. That is, the adhesive layer 12 is provided to correspond to each of the semiconductor chips 10. The adhesive layers 12 are in an uncured state at the stage of preparation.

The adhesive layer 12 is, for example, a film containing a thermosetting adhesive such as a die attach film (DAF). The thermosetting adhesive forming the adhesive layer 12 contains, for example, a polymer resin component and a thermosetting component. A thickness of the adhesive layer 12 is, for example, 50 μm or less. In a case where the thickness of the adhesive layer 12 is 50 μm or less, the adhesive layer 12 can be easily scraped off during the grinding in the step (c). The thickness of the adhesive layer 12 may be 20 μm or less, 10 μm or less, 9 μm or less, 8 μm or less, or 7 μm or less, and may be 1 μm or more, 2 μm or more, 3 μm or more, 4 μm or more, or 5 μm or more. Note that the thickness of the adhesive layer 12 here means the thickness after curing.

A high molecular weight resin component contained in the adhesive layer 12 may contain, for example, at least one resin selected from the group consisting of acrylic rubber, polyimide, and phenoxy resin. The high molecular weight resin component may have a reactive group such as an epoxy group. A weight average molecular weight (value in terms of standard polystyrene by a GPC method) of the high molecular weight resin component may be 100,000 to 3 million. A content of the high molecular weight resin component may be 30 to 80 parts by mass with respect to 10 parts by mass of a total mass of the adhesive layer 12.

The thermosetting component that can be contained in the adhesive layer 12 is a compound having a reactive group that forms a crosslinked structure by self-polymerization and/or reaction with a curing agent. The thermosetting component may contain, for example, at least one selected from the group consisting of an epoxy resin, a bismaleimide resin, a triazine resin, and a phenol resin. A content of the thermosetting component may be 1 to 30 parts by mass with respect to 100 parts by mass of the amount of the adhesive layer 12.

The thermosetting adhesive forming the adhesive layer 12 may contain other components as necessary. Examples of other components include a curing agent that reacts with the thermosetting component, a curing accelerator that accelerates the reaction between the thermosetting component and the curing agent, a coupling agent (for example, a silane coupling agent), and a filler (for example, silica).

The filler contained in the adhesive layer 12 may be an inorganic filler. Specific examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, crystalline silica, and amorphous silica. One kind of these may be used alone or two or more kinds thereof may be used in combination. A content of the filler contained in the adhesive layer 12 may be 50% by mass to 95% by mass based on a total amount of the adhesive layer 12 (adhesive) before curing. Note that the content of the filler contained in the adhesive layer 12 is preferably 60% by mass or more, more preferably 70% by mass or more, particularly preferably 80% by mass or more, and preferably 80% by mass to 95% by mass with respect to the total amount of the adhesive layer 12 (adhesive) before curing.

The carrier 20 is also prepared in the step (a). As the carrier 20, for example, a silicon carrier or the like can be used. The silicon carrier may be monocrystalline silicon or polycrystalline silicon. The carrier 20 has, for example, a thickness of 0.6 to 1.1 mm and a flatness with an arithmetic mean roughness of 50 nm or less. The carrier 20 has, for example, a wafer shape or a panel shape, and is not particularly limited, but may be, for example, a circular wafer having a diameter of 200 mm, a diameter of 300 mm, or a diameter of 450 mm, or a rectangular panel having a side of 200 to 700 mm or less. As the carrier 20, a prepreg having no copper foil may be used.

Subsequently, when the preparation of the plurality of semiconductor chips 10 and the carrier 20 is completed, the plurality of semiconductor chips 10 are fixed on the first carrier surface 20a of the carrier 20 such that each of the connection terminals 10c of the plurality of semiconductor chips 10 faces away from the carrier 20 (in a so-called face-up state), as illustrated in (b) of FIG. 2. This fixation is performed by bonding each of the semiconductor chips 10 to the carrier 20 by the adhesive layer 12 before curing, and then curing the adhesive layer 12 bonded to each of the semiconductor chips 10. Since this fixation is strong, the semiconductor chips 10 cannot move after being fixed to the first carrier surface 20a of the carrier 20. Note that a surface of the carrier 20 on the side opposite to the first carrier surface 20a is the second carrier surface 20b.

Subsequently, the semiconductor chips 10 fixed to the carrier 20 are encapsulated with an encapsulant so as to cover the plurality of semiconductor chips 10 on the carrier 20 as illustrated in (c) of FIG. 2. The encapsulation by the encapsulant can be performed, for example, by molding with a mold. In the manufacturing method according to the present embodiment, since the semiconductor chips 10 are firmly fixed to the carrier 20 by the adhesive layers 12, a phenomenon in which the semiconductor chips 10 are shifted (die shift) does not occur even in a case where the encapsulation by the encapsulant is performed by a molding machine. As a result, an encapsulant layer 30 covering the semiconductor chips 10 is formed.

The encapsulant used as the encapsulant layer 30 may be, for example, an encapsulant containing an epoxy resin, or may contain a curable resin component and an inorganic filler. A content of the inorganic filler in the encapsulant may be 50% by mass or more based on a total amount of the encapsulant before curing. The content of the inorganic filler in the encapsulant is preferably 60% by mass or more, more preferably 70% by mass or more, and particularly preferably 80% by mass or more, based on the total amount of the encapsulant before curing. As an example, the content of the inorganic filler in the encapsulant may be 60% by mass to 90% by mass based on the total amount of the encapsulant before curing. A filler contained in the encapsulant layer 30 may be an inorganic filler. Specific examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, crystalline silica, and amorphous silica. One kind of these may be used alone or two or more kinds thereof may be used in combination.

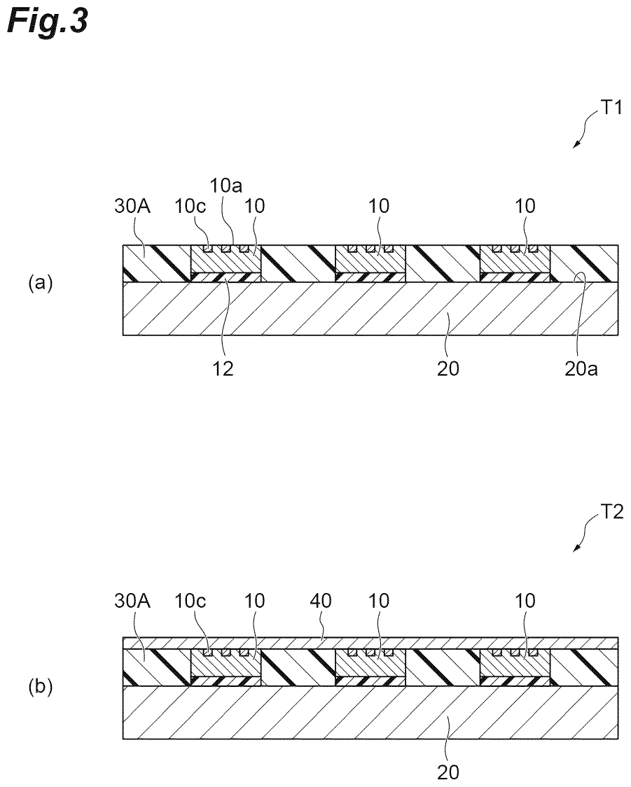

Subsequently, once the semiconductor chips 10 are encapsulated with the encapsulant, the encapsulant layer 30 is ground until the connection terminals 10c (the first chip surfaces 10a) of the semiconductor chips 10 are exposed, as illustrated in (a) of FIG. 3, thereby obtaining the encapsulant layer 30A. In this grinding step, the encapsulant layer 30 may be ground so as to have a grinding amount of, for example, 30 μm or more. A thickness of the ground encapsulant layer 30A may be 50 μm or more, 100 μm or more, or 150 μm or more. As described above, in the step (a), the laminate T1 in which each of the plurality of semiconductor chips 10 is fixed on the carrier 20 by the adhesive layer 12 is formed.

In step (b), the re-distribution layer 40 that connects to each of the connection terminals 10c of the plurality of semiconductor chips 10 is formed as illustrated in (b) of FIG. 3. In the step of forming the re-distribution layer 40, a distance between wirings, which are conductor portions, is formed so as to gradually increase as a distance from the semiconductor chip 10 increases (toward the upper side in the drawing). In the example illustrated in (b) of FIG. 3, the re-distribution layer 40 is formed on the first chip surfaces 10a of the plurality of semiconductor chips 10 and a surface of the encapsulant layer 30A. Note that the re-distribution layer 40 can be formed by using a conventional method, and thus detailed description thereof is omitted. As described above, the laminate T2 provided with the re-distribution layer 40 is formed.

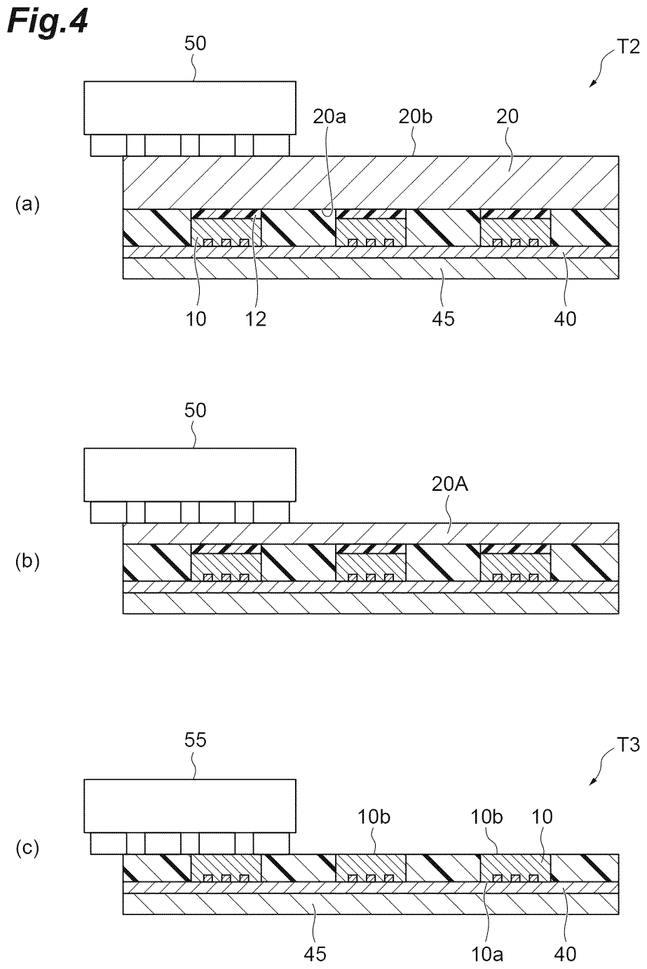

In the step (c), once the re-distribution layer 40 is formed, the carrier 20 in the laminate T2 is ground from the second carrier surface 20b toward the first carrier surface 20a while protecting the re-distribution layer 40 with a back grinding (BG) tape 45 or the like. In this grinding step, first, the carrier 20 is roughly ground by a first grindstone 50 from the second carrier surface 20b toward the first carrier surface 20a as illustrated in (a) to (b) of FIG. 4. The first grindstone 50 is, for example, a grindstone with a grain size of #200 to #1000. In the rough-grinding, the carrier 20 is first scraped off, and then the adhesive layers 12 and a surface portion of the encapsulant layer 30A (a region in the same layer as the adhesive layers 12) are scraped off. At this time, the grinding may be performed until the second chip surfaces 10b of the semiconductor chips 10 are exposed, or the grinding may be performed until just before the second chip surface 10b of the semiconductor chip 10 is exposed. Note that, in a case where the carrier 20 made of silicon is ground, silicon sludge (waste) ground mainly by the rough-grinding may be recovered and reused.

Subsequently, just before or when the second chip surfaces 10b of the semiconductor chips 10 are exposed by the rough-grinding, a roughly ground carrier 20A is subjected to finish-grind with a second grindstone 55 having a higher grain size than the first grindstone 50 as illustrated in (c) of FIG. 4. The second grindstone 55 is a grindstone having a grain size of #2000 to #6000. In the finish-grinding step, the second chip surfaces 10b of the semiconductor chips 10 and the surface of the encapsulant layer 30A are polished. As a result, cleanliness of the second chip surfaces 10b of the semiconductor chips 10 encapsulated in the encapsulant layer 30A is improved. As described above, the laminate T3 including the plurality of semiconductor chips 10 provided with the re-distribution layer 40 is formed.

In the step (d), the laminate T3 from which the carrier 20 has been scraped off is diced into individual pieces to obtain semiconductor devices each including the semiconductor chip 10. Note that the bumps may be attached to the re-distribution layer 40 before the dicing. As described above, it is possible to obtain a plurality of the semiconductor devices 1 illustrated in FIG. 1.

As described above, the plurality of semiconductor chips 10 are fixed on the carrier 20 by the adhesive layers 12 in the method for manufacturing a semiconductor device according to the present embodiment. As described above, the semiconductor chips 10 are firmly fixed to the carrier 20 by the adhesive layers 12 that perform fully fixing instead of temporary fixing. In this case, displacement of the semiconductor chips 10 is reliably prevented. In addition, in this method for manufacturing a semiconductor device, in the grinding step, the carrier 20 is scraped off to expose the second chip surfaces 10b of the plurality of semiconductor chips 10, wherein the second chip surfaces 10b locates on opposite side of the first chip surfaces 10a on which the re-distribution layer 40 is provided. In this case, since the carrier 20 is scraped off, it is possible to improve the cleanliness of the chip surfaces without leaving a resin residue or the like.

In the method for manufacturing a semiconductor device according to the present embodiment, the adhesive layer 12 may be a layer obtained by curing the thermosetting adhesive and provided to correspond to each of the plurality of semiconductor chips 10. As a result, the adhesive layer 12 can be easily ground at the time of grinding the carrier 20.

In the method for manufacturing a semiconductor device according to the present embodiment, the thickness of the adhesive layer 12 can be 50 μm or less. In this case, the adhesive layer 12 can be easily ground in the grinding the carrier 20.

In the method for manufacturing a semiconductor device according to the present embodiment, the adhesive layer 12 contains the curable resin component and the inorganic filler, and the content of the inorganic filler can be 50% by mass to 95% by mass based on the total amount of the adhesive before the adhesive layer 12 is cured. In this case, the adhesive layer 12 can be easily ground in the grinding the carrier 20.

In the method for manufacturing a semiconductor device according to the present embodiment, the step of preparing the laminate T1 includes a step of fixing each of the plurality of semiconductor chips 10 to the carrier 20 with the adhesive layer 12, and step of forming the encapsulant layer 30 by encapsulating the plurality of semiconductor chips 10 on the carrier 20 with the encapsulant to cover the plurality of semiconductor chips 10. The encapsulant may contain the curable resin component and the inorganic filler, and the content of the inorganic filler in the encapsulant may be 50% by mass or more based on the total amount of the encapsulant before curing. In this case, the encapsulant layer 30 can be reliably ground.

In the method for manufacturing a semiconductor device according to the present embodiment, the step of preparing the laminate T1 may further include, a step of grinding the encapsulant layer 30 covering the plurality of semiconductor chips 10 until the first chip surfaces 10a of the plurality of semiconductor chips 10 are exposed, after the step of encapsulating.

In the method for manufacturing a semiconductor device according to the present embodiment, the step of grinding the carrier 20 includes a step of rough-grinding the second carrier surface 20b of the carrier 20 with the first grindstone 50, and a step of finish-grinding the roughly ground carrier 20A with the second grindstone 55 having a higher grain size than the first grindstone 50. The grinding speed of the carrier 20 can be accelerated by the rough-grinding, and the finish of the ground surface can be improved by the finish-grinding. The first grindstone may be a grindstone having a grain size of #200 to #1000, and the second grindstone may be a grindstone having a grain size of #2000 to #6000. As a result, it is possible to more reliably improve the grinding speed and the finish accuracy of the ground surface. In addition, in the rough-grinding step, the carrier 20 and at least parts of the adhesive layers 12 may be scraped off by the first grindstone 50. In the finish-grinding step, the encapsulant layer 30A and the second chip surfaces 10b of the semiconductor chips 10 may be polished by the second grindstone 55. As a result, it is possible to more reliably improve the grinding speed and the finish accuracy of the ground surface.

In the method for manufacturing a semiconductor device according to the present embodiment, the carrier 20 may be a silicon carrier. The grinding step may further include a step of recovering the ground silicon sludge for reuse. In this case, the used silicon can be reused, and the manufacturing method can be made environmentally friendly.

Although the semiconductor device manufacturing method according to the embodiment of the present disclosure has been described above, the present disclosure is not limited to the above-described embodiment, and can be appropriately changed without departing from the gist of the present disclosure.

### REFERENCE SIGNS LIST

1 Semiconductor device
10 Semiconductor chip
10a First chip surface
10b Second chip surface
10c Connection terminal
12 Adhesive layer
20, 20A Carrier
20a First carrier surface
20b Second carrier surface
30, 30A Encapsulant layer
40 Re-distribution layer
50 First grindstone
55 Second grindstone
T1, T2 Laminate.

1. A method for manufacturing a semiconductor device, the method comprising:
preparing a laminate in which each of a plurality of semiconductor chips is fixed on a carrier by an adhesive layer, wherein the plurality of semiconductor chips are fixed on a first carrier surface of the carrier such that each connection terminal of the plurality of semiconductor chips faces away from the carrier;
forming a re-distribution layer that connects to each connection terminal of the plurality of semiconductor chips; and
grinding the carrier in the laminate from a second carrier surface opposite to the first carrier surface toward the first carrier surface,
wherein, in the grinding, the carrier and the adhesive layer are scraped off to expose second chip surfaces of the plurality of semiconductor chips, and
wherein the second chip surfaces are located on opposite side of first chip surfaces on which the re-distribution layer is provided.

2. The method for manufacturing a semiconductor device according to claim 1,
wherein the adhesive layer is a layer obtained by curing a thermosetting adhesive and provided to correspond to each of the plurality of semiconductor chips.

3. The method for manufacturing a semiconductor device according to claim 1, wherein a thickness of the adhesive layer is 50 μm or less.

4. The method for manufacturing a semiconductor device according to claim 3, wherein the thickness of the adhesive layer is 20 μm or less.

5. The method for manufacturing a semiconductor device according to claim 1,
wherein the adhesive layer includes a curable resin component and an inorganic filler, and
wherein a content of the inorganic filler is 50% by mass to 95% by mass based on a total amount of an adhesive before the adhesive layer is cured.

6. The method for manufacturing a semiconductor device according to claim 5,
wherein the content of the inorganic filler is 80% by mass to 95% by mass based on the total amount of the adhesive before the adhesive layer is cured.

7. The method for manufacturing a semiconductor device according to claim 1,
wherein the preparing the laminate includes:
fixing each of the plurality of semiconductor chips to the carrier with the adhesive layer; and
forming an encapsulant layer by encapsulating the plurality of semiconductor chips on the carrier with an encapsulant to cover the plurality of semiconductor chips.

8. The method for manufacturing a semiconductor device according to claim 7,
wherein the encapsulant includes a curable resin component and an inorganic filler, and
wherein a content of the inorganic filler in the encapsulant is 50% by mass or more based on a total amount of the encapsulant.

9. The method for manufacturing a semiconductor device according to claim 7,
wherein the preparing the laminate further includes:
grinding the encapsulant layer covering the plurality of semiconductor chips until the first chip surfaces of the plurality of semiconductor chips are exposed, after the forming of the encapsulant layer.

10. The method for manufacturing a semiconductor device according to claim 1,
wherein the grinding of the carrier includes:
rough-grinding the second carrier surface of the carrier with a first grindstone; and
finish-grinding the roughly ground carrier with a second grindstone having a higher grain size than the first grindstone.

11. The method for manufacturing a semiconductor device according to claim 10,
wherein the first grindstone is a grindstone having a grain size of #200 to #1000, and
wherein the second grindstone is a grindstone having a grain size of #2000 to #6000.

12. The method for manufacturing a semiconductor device according to claim 10, wherein, in the rough-grinding, the carrier and at least a part of the adhesive layer are scraped off by the first grindstone.

13. The method for manufacturing a semiconductor device according to claim 10, wherein, in the finish-grinding, the encapsulant layer and the second chip surfaces of the semiconductor chips are polished by the second grindstone.

14. The method for manufacturing a semiconductor device according to claim 1,
wherein the carrier includes a silicon carrier, and
wherein the grinding further includes recovering ground silicon sludge for reuse.
